(19) United States
(12) Patent Application Publication
(10) Pub. No.: US 2026/0371645 A1
(43) Pub. Date: Nov. 19, 2026

(54) HIGH VOLTAGE DEPLETION DEVICE DESIGN RESISTANT TO HIGH DRAIN VOLTAGE INDUCED PINCH OFF VOLTAGE SHIFT

(71) Applicant: Microchip Technology Incorporated, Chandler, AZ (US)

(72) Inventors: Robin (Haibing) Liu, Fremont, CA (US); Pejman Khosropour, Campbell, CA (US); Sajid Kabeer, Mesa, AZ (US); Yan Tan, Phoenix, AZ (US); Eleonore Daemen, Trets (FR)

(21) Appl. No.: 19/372,047

(22) Filed: Oct. 28, 2025

Related U.S. Application Data
(60) Provisional application No. 63/808,301, filed on May 19, 2025.

(51) Int. Cl. H10D 30/65; H10D 30/01; H10D 62/10; H10D 64/00

(52) U.S. Cl. CPC H10D 30/65; H10D 30/0281; H10D 62/116; H10D 64/111

(57) ABSTRACT

A high voltage depletion device is provided. The high voltage depletion device may include a gate structure to control a channel region within the depletion device, wherein the gate structure is electrically isolated from a field plate structure. The field plate structure is to enhance breakdown voltage within the depletion device, wherein the gate structure is to remain unaffected by a drain voltage applied to a drain terminal of the depletion device.

### CROSS-REFERENCE TO RELATED APPLICATION

The present application claims priority from U.S. Provisional Patent Application No. 63/808,301, filed May 19, 2025, which is incorporated herein by reference in its entirety.

### TECHNICAL FIELD

The present disclosure relates generally to high voltage semiconductor devices, and more specifically to high voltage depletion devices designed to reduce pinch off voltage shift under elevated drain voltage conditions.

### BACKGROUND

High voltage depletion devices are widely employed in circuit designs to sustain elevated voltage conditions and regulate current flow. In conventional designs, a single poly gate structure performs dual functions: controlling the on/off state of the channel and serving as a field plate to enhance breakdown voltage (BV). However, under high drain voltage conditions, these devices encounter a challenge referred to as pinch off voltage shift. This challenge arises when the electric potential from the high drain voltage affects the gate control region, making it difficult for the gate to maintain a stable depletion region. As a result, the gate requires higher pinch off voltages, which may become impractical in certain use cases.

Efforts to address this issue generally involve adjusting the doping concentration of the depletion region or incorporating a separate body region to assist in depletion control. These approaches introduce trade-offs, including increased device area, decreased current-handling capacity, and additional circuit design complexity. These factors create constraints for the scalability and performance of high voltage depletion devices as breakdown voltage requirements rise across various circuit applications. Therefore, there exists a need for high voltage depletion devices that can maintain stable performance under elevated drain voltage conditions without introducing undesirable size, current capacity, or design complexity constraints.

### SUMMARY

According to an aspect of one or more examples, there is provided a high voltage depletion device. The depletion device comprises a substrate that includes a body region of a first dopant type, which itself comprises a source terminal positioned in a channel region. The substrate further includes a drain region of a second dopant type, which itself comprises a drain terminal. A gate structure is provided to control current flow in the high voltage depletion device, and a field plate structure is also included. The gate structure may be electrically isolated from the field plate structure. In some aspects, the gate structure and the field plate structure are separately formed from conductive materials. The field plate structure can extend over a drift region within the drain region that is positioned between the drain terminal and the gate structure. The gate structure can include a first end and a second end. This first end can be located above the channel region. In some aspects, the second end can be located between the body region and the drain region, can be aligned with an edge of the drain region, or can overlap with the drain region. An isolation region may be formed in the drain region and the second end of the gate structure may be spaced apart from the isolation region. The isolation region can be an oxide layer selected from shallow trench isolation (STI), local oxidation of silicon (LOCOS), or field oxide. Aspects of the field plate structure may be electrically connected to the source terminal of the depletion device through a contact and a first metal layer. Other aspects of the field plate structure can be configured to connect to the gate structure or a voltage supply positioned between the source terminal and the drain terminal. The substrate can be made from silicon, silicon with an epitaxial layer, or a silicon-on-insulator (SOI) wafer.

According to an aspect of one or more examples, there is provided a method of forming a high voltage depletion device. The method can include forming a body region of a first dopant type in a substrate, forming a drain region of a second dopant type in the substrate, forming a drain terminal in the drain region, forming a source terminal in a channel region within the body region, and forming a gate structure above the channel region to control current flow in the high voltage depletion device. The gate structure includes a first end and a second end, where the first end is located above the channel region. The method can also include forming a field plate structure above the drain region. The gate structure may be electrically isolated from a field plate structure. The field plate structure can extend over a drift region within the drain region that is positioned between the drain terminal and the gate structure. In some aspects, the second end can be located between the body region and the drain region or can be aligned with an edge of the drain region. The method can further include forming an isolation region in the drain region. In this operation, the second end of the gate structure can overlap with the drain region and can be spaced apart from the isolation region. The method can also form a contact and a first metal layer. Here, the field plate structure can be electrically connected to the source terminal through the contact and the first metal layer.

According to an aspect of one or more examples, there is provided a device. The device may include a substrate that includes a body region of a first dopant type, which comprises a source terminal positioned in a channel region, and a drain region of a second dopant type, comprising both an isolation region and a drain terminal. The device further includes a gate structure to control current flow in the high voltage depletion device. The gate structure has a first end located above the channel region and a second end. A field plate structure is also included, where the gate structure is electrically isolated from the field plate structure. Additionally, the device comprises a contact and a first metal layer to connect the source terminal and the field plate structure. The second end can be positioned between the body region and the drain region, aligned with an edge of the drain region, or positioned to overlap with the drain region and spaced apart from the isolation region.

According to an aspect of one or more examples, there is provided a high voltage depletion device. The high voltage depletion device may include a gate structure to control a channel region within the depletion device, wherein the gate structure is electrically isolated from a field plate structure, and the field plate structure is to enhance breakdown voltage within the depletion device, wherein the gate structure is to remain substantially unaffected by a drain voltage applied to a drain terminal of the depletion device. The gate structure and the field plate structure may be formed from separate conductive materials. The field plate structure may extend over a drift region positioned between the drain terminal and the gate structure. The gate structure may be positioned along a boundary of a high voltage well region to reduce the influence of the drain voltage on a pinch off voltage of the device. The boundary location of the gate structure may be selected from a location between a body region and the high voltage well region, a location inside the high voltage well region, spaced apart from a shallow trench isolation (STI) region, and a location aligned with an edge of the high voltage well region. The field plate structure may be electrically connected to a source terminal of the depletion device through a contact and a first metal layer. The field plate structure may be alternatively configured to connect to a gate terminal or a voltage supply positioned between the source terminal and the drain terminal. The depletion device may be implemented on a substrate selected from silicon, silicon with an epitaxial layer, or a silicon-on-insulator (SOI) wafer. The field plate structure may be designed with a length and spacing selected to achieve a desired breakdown voltage. The drift region may be formed in an oxide layer selected from shallow trench isolation (STI), local oxidation of silicon (LOCOS), or field oxide. The depletion device may be an N-type high voltage depletion device. The depletion device may be a P-type high voltage depletion device. The gate structure may be positioned adjacent to a P-body region within the high voltage well region.

According to an aspect of one or more examples, there is provided a method of operating a high voltage depletion device. The method may include applying a drain voltage to a drain terminal of the depletion device, maintaining a gate voltage at a gate terminal to control a channel region of the depletion device, wherein the gate structure is electrically decoupled from a field plate structure, and configuring the field plate structure to enhance the breakdown voltage and reduce the effect of the drain voltage on a pinch off voltage of the device. The method may include positioning the gate structure to provide a balance between pinch off voltage tolerance and on-state resistance. The method may include connecting the field plate structure electrically to a source terminal of the depletion device. The depletion device may include a substrate selected from an N-type or P-type well with a corresponding body region. The field plate structure may be formed from a conductive material selected from polysilicon, a metal gate, or a thin-film resistor.

According to an aspect of one or more examples, there is provided a system. The system may include a circuit including a high voltage depletion device, the depletion device including a gate structure and a field plate structure, wherein the gate structure is electrically isolated from the field plate structure, and the field plate structure to maintain breakdown voltage characteristics while mitigating the influence of a drain voltage on a pinch off voltage of the gate structure. The high voltage depletion device may be implemented in a power management circuit or a high-voltage switching application.

### BRIEF DESCRIPTION OF DRAWINGS

FIG. 1 shows a cross-sectional view of an N-type high voltage depletion device according to various examples.

FIG. 2 shows a cross-sectional view of a P-type high voltage depletion device according to various examples.

FIG. 3 shows a flowchart of a method for operating a high voltage depletion device according to various examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

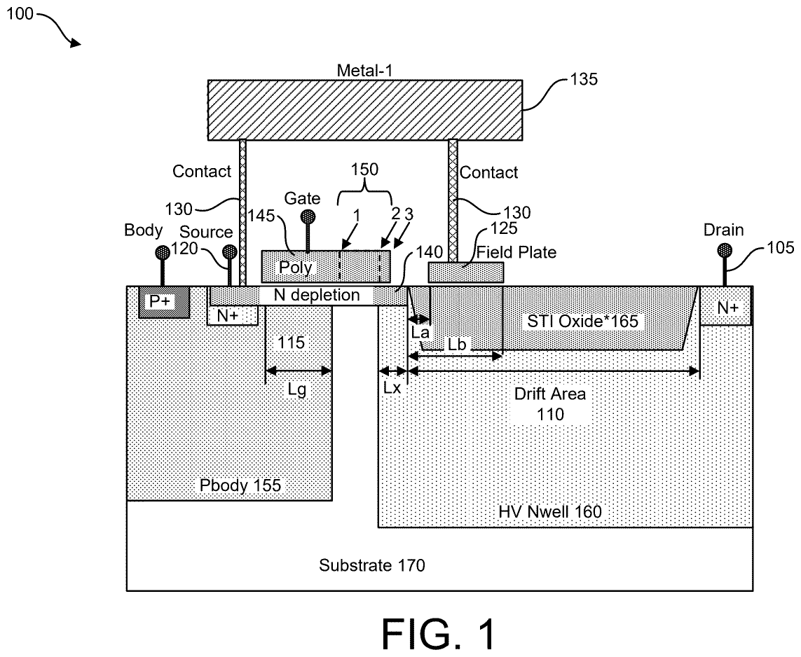

FIG. 1 shows a cross-sectional view of an N-type high voltage depletion device 100 according to various examples. The device 100 may be designed to manage high drain voltage conditions while maintaining control over pinch off voltage and enabling stable breakdown voltage performance. The device 100 may include a variety of regions and components that contribute to current regulation, field distribution, and voltage handling.

The device 100 may be implemented on a substrate 170, which may include silicon, silicon with an epitaxial layer, or silicon-on-insulator (SOI), without limitation. The substrate 170 may provide structural support, electrical isolation, and stability for high-voltage operation. The substrate 170 may contribute to overall device 100 performance by interacting with a drift area or region 110 and other active areas to control parasitic effects and ensure reliable isolation under elevated electric field conditions. A body region 155 of a first dopant type may be formed in the substrate 170. In the example of FIG. 1, the body region 155 is a P-body region made of p-type material. A drain region 160 of a second dopant type may also be formed in the substrate 170. In the example of FIG. 1, the drain region 160 is an N-type region made of an n-type material. The drain region 160 may have a dopant concentration to accommodate high voltage, such that drain region 160 may be a high voltage (HV) N-well.

The device 100 may include a drain terminal 105 that may be formed in the HV N-well drain region 160, and may have a higher doping concentration than the HV N-well drain region 160. The drain terminal 105 may receive a high drain voltage (Vdd), causing an electric field to form across the device 100. This field may primarily extend across the drift area or region 110, which is located between the drain terminal 105 and a depletion region 140. The drift region 110 may serve to distribute the electric field, reducing intensity near sensitive components to prevent premature breakdown.

A shallow trench isolation (STI) oxide 165 may be formed at a top surface of the HV N-well drain region 160, and may electrically isolate active regions within the device 100, limiting parasitic currents and defining the drift region 110 boundaries. Alternative isolation structures, such as local oxidation of silicon (LOCOS) or field oxide, may also be employed depending on process technology.

A source terminal 120 may be located on the opposite side of the device 100 and may provide a return path for current flow. The source terminal 120 may also provide a stable reference point for electric field management. The source terminal 120 may be formed in a channel region 115 within the body region 155, and may be doped using a different doping material than the body region 155, and may have a higher dopant concentration than the body region. For example, the channel region 115 in FIG. 1 may be an N+ region formed in the p-type body region 155. A body terminal may be formed in the body region 155, and may be doped with the same type of dopant material as the body region 155. For example, the body terminal of FIG. 1 may be a P+ region formed within the p-type body region 155.

A gate terminal 145 may be positioned above the channel region 115 and may control the depletion region 140 to regulate current flow. The gate terminal 145 may be formed from a conductive material such as polysilicon, metal, or another compatible conductive layer. For example, the device 100 of FIG. 1 includes a gate terminal 145 made of polysilicon (Poly).

In various examples, a field plate structure 125 may be formed above the STI oxide 165 and may be electrically connected to the source terminal 120 through a contact 130 and a first metal layer 135 (Metal-1). Alternatively, the field plate structure 125 may be connected to a gate terminal or to another intermediate voltage supply depending on circuit design considerations. As shown in FIG. 1, the field plate structure 125 is separate from the gate terminal 145, which may allow the field plate structure 125 to control the breakdown voltage while limiting the impact of the drain voltage on the pinch off voltage of the channel region 115.

The channel region 115 (which has a length Lg) may provide a controlled path for current flow between the source terminal 120 and the drain terminal 105. The depletion region 140 covers the channel region 115. Voltage applied to gate 145 controls the on-state and off-state of the device 100.

The location of an edge 150 of the gate terminal 145 may influence the pinch off voltage behavior and on-state resistance (Ron) of device 100. Depending on the design considerations, the gate edge 150 may be positioned in one of the following configurations (designated as positions 1, 2, and 3 in FIG. 1): (1) between the P-type body region 155 and the HV N-well drain region 160, which may improve immunity to drain voltage shifts but may increase Ron; (3) inside the HV N-well drain region 160, but spaced apart from the STI oxide 165, which may decrease Ron but may offer less immunity from drain voltage influence; and (2) aligned with the edge of the HV N-well drain region 160, achieving a compromise between drain voltage immunity and on-state resistance Ron.

The field plate structure 125 may extend over the drift region 110 and may influence electric field distribution to enhance breakdown voltage performance. The length Lb that the field plate 125 extends into the STI oxide 165, and the horizontal spacing La between the field plate 125 and the depletion region 140 (which extends into the HV N-well drain region 160 by a length Lx) may be designed to balance electric field behavior.

Contacts 130 may provide electrical interfaces for connecting the source terminal 120, drain terminal 105, gate structure 145, and field plate structure 125 to external circuitry. These contacts 130 may interact with metal layers 135, enabling the routing of signals and power within the circuit.

During operation, the N-type high voltage depletion device 100 may regulate current flow by controlling the depletion region 140 and electric field distribution. The coordination of the gate structure 145, field plate structure 125, and drift region 110 may enable stable performance under high-voltage conditions, making the device 100 suitable for power management and switching applications.

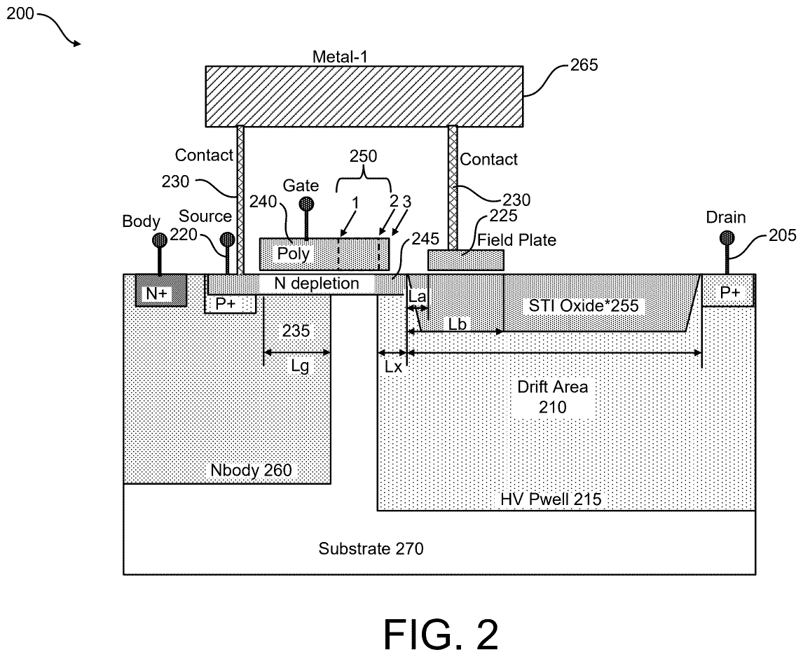

FIG. 2 shows a cross-sectional view of a P-type high voltage depletion device 200 according to various examples. The device 200 may regulate current flow and control pinch off voltage under elevated drain voltage conditions. The device 200 may share similar design elements with the N-type device 100, but with P-type doping and well regions.

The drain terminal 205 may be positioned on the right-hand side of the device 200 and may receive a high drain voltage (Vdd). The application of this voltage may generate an electric field across the drift area or region 210, which may extend through a portion of high voltage P-well (HVPwell) 215. The drift region 210 may distribute the electric field to reduce the risk of breakdown and improve device 200 stability.

The source terminal 220 may be located on the left-hand side of the device 200 and may provide a return path for current flow. The field plate structure 225 may be electrically connected to the source terminal 220 through a contact 230, providing a stable reference point for electric field control.

The channel region 235 (which has a length Lg) may be situated beneath the gate structure 240 and may control current flow between the source terminal 220 and drain terminal 205. The depletion region 245 covers the channel region 235. Voltage applied to gate 240 controls the on-state and off-state of the device 200.

The gate structure 240 may control the depletion region 245. The position of the poly gate edge 250 may affect both on-state resistance (Ron) and the pinch off voltage of the channel region 235. Placement options may include configurations similar to those described for the N-type device 100.

The field plate structure 225 may extend above a portion of the drift region 210 and may enhance breakdown voltage by managing electric field distribution. The field plate structure 225 is separate from the gate terminal 240, which may allow the field plate structure 225 to control the breakdown voltage while limiting the impact of the drain voltage on the pinch off voltage of the channel region 235. The spacing (La) between the field plate structure 225 and the end of the drift area 210, and the length (Lb) that the field plate 225 extends past the end of the STI oxide 255, may be adjusted to control the breakdown voltage of the device.

The high voltage P-well region 215 may form the drift path, while the N-body region 260 may assist in controlling depletion behavior and voltage stability. The STI oxide 255 may provide isolation to limit leakage currents. Depending on the process, LOCOS or field oxide may also be used. Contacts 230 may connect the device 200 terminals to external circuits, with metal layers 265 supporting power and signal routing. The device 200 may be fabricated on a substrate 270 designed to provide structural and electrical isolation.

During operation, the P-type high voltage depletion device 200 may regulate current flow and maintain pinch off voltage stability by coordinating the gate structure 240, field plate structure 225, and drift region 210. The device 200 may provide reliable performance in high-voltage applications such as power management and switching.

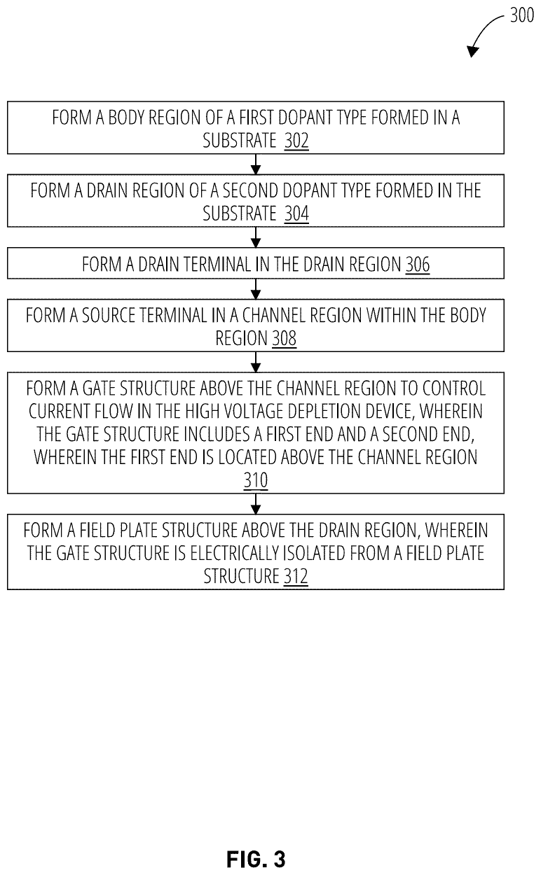

FIG. 3 shows a flowchart of a method 300 for operating a high voltage depletion device according to various examples. At operation 302, a body region of a first dopant type formed in a substrate is formed. At operation 304, a drain region of a second dopant type formed in the substrate is formed. At operation 306, a drain terminal is formed in the drain region. At operation 308, a source terminal is formed in a channel region within the body region. At operation 310, a gate structure is formed above the channel region to control current flow in the high voltage depletion device. The gate structure includes a first end and a second end. The first end is located above the channel region. The second end can be located between the body region and the drain region. The second end can be aligned with an edge of the drain region. At operation 312, a field plate structure can be formed above the drain region. The gate structure is electrically isolated from a field plate structure. The field plate structure can extend over a drift region within the drain region that is positioned between the drain terminal and the gate structure. Method 300 can also include forming an isolation region in the drain region. The second end of the gate structure can overlap with the drain region and be spaced apart from the isolation region. Method 300 can further include forming a contact and a first metal layer. The field plate structure can be electrically connected to the source terminal through the contact and the first metal layer.

It may be noted that the flowchart is explained to have above stated operations; however, those skilled in the art would appreciate that the flowchart may have more/less number of operations, which may enable all of the above stated examples in the present disclosure.

Various examples have been disclosed herein, in connection with the above description and the drawings. It will be understood that it would be unduly repetitious to literally describe and illustrate every combination and sub combination of these examples. Accordingly, all examples can be combined in any way or combination, and the present specification, including the drawings, shall be construed to constitute a complete written description of all combinations and sub combinations of the examples described herein, and of the manner and process of making and using them, and shall support claims to any such combination or sub combination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A high voltage depletion device, the depletion device comprising:
a substrate, comprising:
a body region of a first dopant type, comprising a source terminal positioned in a channel region; and
a drain region of a second dopant type, comprising a drain terminal;
a gate structure to control current flow in the high voltage depletion device; and
a field plate structure;
wherein the gate structure is electrically isolated from a field plate structure.

2. The high voltage depletion device of claim 1, wherein the gate structure and the field plate structure are separately formed from conductive materials.

3. The high voltage depletion device of claim 1, wherein the field plate structure extends over a drift region within the drain region that is positioned between the drain terminal and the gate structure.

4. The high voltage depletion device of claim 1, wherein the gate structure includes a first end and a second end, wherein the first end is located above the channel region.

5. The high voltage depletion device of claim 4, wherein the second end is located between the body region and the drain region.

6. The high voltage depletion device of claim 4, wherein the second end is aligned with an edge of the drain region.

7. The high voltage depletion device of claim 4, wherein the second end overlaps with the drain region.

8. The high voltage depletion device of claim 7, wherein the drain region comprises an isolation region, and wherein the second end of the gate structure is spaced apart from the isolation region.

9. The high voltage depletion device of claim 8, wherein the isolation region is an oxide layer selected from shallow trench isolation (STI), local oxidation of silicon (LOCOS), or field oxide.

10. The high voltage depletion device of claim 1, wherein the field plate structure is electrically connected to the source terminal of the depletion device through a contact and a first metal layer.

11. The high voltage depletion device of claim 1, wherein the field plate structure is configured to connect to the gate structure or a voltage supply positioned between the source terminal and the drain terminal.

12. The high voltage depletion device of claim 1, wherein the substrate is made from silicon, silicon with an epitaxial layer, or a silicon-on-insulator (SOI) wafer.

13. A method of forming a high voltage depletion device, the method comprising:
forming a body region of a first dopant type in a substrate;
forming a drain region of a second dopant type in the substrate;
forming a drain terminal in the drain region;
forming a source terminal in a channel region within the body region;
forming a gate structure above the channel region to control current flow in the high voltage depletion device, wherein the gate structure includes a first end and a second end, wherein the first end is located above the channel region; and
forming a field plate structure above the drain region;
wherein the gate structure is electrically isolated from a field plate structure.

14. The method of claim 13, wherein the field plate structure extends over a drift region within the drain region that is positioned between the drain terminal and the gate structure.

15. The method of claim 13, wherein the second end is located between the body region and the drain region.

16. The method of claim 13, wherein the second end is aligned with an edge of the drain region.

17. The method of claim 13, comprising forming an isolation region in the drain region;
wherein the second end of the gate structure overlaps with the drain region and is spaced apart from the isolation region.

18. The method of claim 13, comprising forming a contact and a first metal layer, wherein the field plate structure is electrically connected to the source terminal through the contact and the first metal layer.

19. A device comprising:
a substrate, comprising:
a body region of a first dopant type, comprising a source terminal positioned in a channel region; and
a drain region of a second dopant type, comprising an isolation region and a drain terminal;
a gate structure to control current flow in the high voltage depletion device, the gate structure having a first end and a second end, wherein the first end is located above the channel region;
a field plate structure, wherein the gate structure is electrically isolated from the field plate structure; and
a contact and a first metal layer to connect the source terminal and the field plate structure.

20. The device of claim 19, wherein the second end is (1) positioned between the body region and the drain region, (2) aligned with an edge of the drain region, or (3) positioned to overlap with the drain region and spaced apart from the isolation region.
